(19) United States
(12) Patent Application Publication
(10) Pub. No.: US 2026/0029452 A1
(43) Pub. Date: Jan. 29, 2026

(54) SYSTEM AND METHOD FOR DETERMINING VEHICLE OPERATIONAL STATE

(71) Applicant: Joseph & Roberts, LLC, Las Vegas, NV (US)

(72) Inventor: Brian David Feldman, Macungie, PA (US)

(21) Appl. No.: 19/274,846

(22) Filed: Jul. 21, 2025

Related U.S. Application Data
(60) Provisional application No. 63/674,742, filed on Jul. 23, 2024.

(51) Int. Cl. G01R 31/00; B60R 16/033

(52) U.S. Cl. CPC G01R 31/006; B60R 16/033

(57) ABSTRACT

A system for determining vehicle operational state includes an electrical parameter detector configured to be installed in a vehicle fuse box and a power controller in communication with the electrical parameter detector. The electrical parameter detector is configured to determine the state of vehicle operation by monitoring current draw and/or voltage differentials across points of a given fuse or relay in the fuse box of the vehicle. When the appropriate current draw and/or voltage differential is detected, a wireless signal may be sent to the power controller inside the cabin of the vehicle. When the power controller receives the appropriate wireless signal from the electrical parameter detector, it is configured to activate an accessory device intended to be activated only when the vehicle is operational. The power controller is also configured to turn off power-consuming accessory devices when the vehicle is not operational in order to eliminate parasitic power draws from such vehicle accessories.

### CROSS-REFERENCE TO RELATED APPLICATIONS

This application claims priority to U.S. Provisional Patent Application No. 63/674,742, the entire contents of which are incorporated by reference herein.

### FIELD

The present disclosure relates to electrical power supplies, and particularly to systems and methods used to provide power to accessories used in motor vehicles.

### BACKGROUND

Many vehicles today are equipped with accessory components which require power from the vehicle for operation. Examples of accessory components for vehicles (which may also be referred to herein as simply vehicle “accessories”) include dashboard cameras, radar detectors, lighting kits, audio/video units, and any number of additional accessories as will be recognized by those of ordinary skill in the art. In most situations, power to the accessory components is desired when the vehicle is on, and power to the accessory components is not desired when the vehicle is turned off. However, determining the operational state in modern vehicles is not always straightforward.

While many cars have some type of power connector that is switched on with the ignition and are helpful in determining vehicle operational state in certain situations, such power connectors are typically unique to every vehicle model such that connecting to and communicating with every type of power connector in every vehicle model is difficult and inefficient. Moreover, these power connectors are typically located in an inconvenient location that is difficult to access (e.g., under the dashboard). This makes a common installation for a power connector in a fleet of passenger vehicles impractical.

Previously, the battery voltage of a vehicle was generally a good indicator that a vehicle was running because the vehicle's battery would be charged by the alternator when the engine was running, which caused the vehicle's electrical system and battery to have a significantly higher voltage than when the car was off (e.g., approximately 14-14.4V with the vehicle engine running vs. approximately 12.6V with the vehicle engine off). In recent years developments such as “smart alternators” and hybrid powertrains have started to comprise a significant portion of the automotive fleet with such features and such developments render the sole use of battery voltage unreliable to determine the operational state of the vehicle.

In view of the foregoing, it would be desirable to provide a device for a vehicle accessory that is capable of determining the operational state of the vehicle. It would be advantageous for such device to determine the operational state without predominant reliance on the battery voltage of the vehicle. It would also be advantageous if such device were configured to provide power to the vehicle accessory dependent on various different vehicle operational states.

### SUMMARY

A system for detecting vehicle operational state is disclosed herein. The system includes a vehicle, an electrical parameter detector, a power controller, and a vehicle accessory. The vehicle includes a vehicle fuse box comprising a plurality of receptacles. The electrical parameter detector is configured for insertion into one of the plurality of receptacles in the vehicle fuse box. The electrical parameter detector is further configured to detect an electrical parameter indicative of a vehicle operational state. The power controller is mounted outside of the vehicle fuse box. The power controller is in communication with the electrical parameter detector and is configured to receive a signal from the electrical parameter detector indicative of an operational state of the vehicle. The vehicle accessory is connected to the power controller. The power controller is further configured to deliver power to the vehicle accessory based on the operational state of the vehicle.

In at least one embodiment, a method is disclosed for determining vehicle operational state. The method comprises detecting an electrical parameter within a vehicle fuse box. The method further comprises determining a vehicle operational state based on the detected electrical parameter. Thereafter, the method comprises controlling power delivered to a vehicle accessory based at least in part on the determined vehicle operational state.

In yet another embodiment a system is disclosed for determining vehicle operational state. The system includes an electrical parameter detector and a power controller. The electrical parameter detector is connected to a vehicle electrical circuit and is configured to detect electrical parameter indicative of a vehicle operational state. The power controller is connected to a vehicle power circuit within a vehicle cabin and is in wireless communication with the electrical parameter detector. The power controller includes switching circuitry configured to deliver power to a vehicle accessory depending on the vehicle operational state.

As disclosed herein, the electrical parameter detector may be specifically configured to accurately determine whether (i) the vehicle is operational with the powertrain running (e.g., an engine or electric motor of the vehicle running), or (ii) not operational with the powertrain not running. Additionally, the system is configured to minimize power consumption of a vehicle accessory when the vehicle is not in operation to avoid draining battery and causing the engine control module (ECM) to trigger fault codes for excess power consumption. The system is further configured to avoid interference with the vehicle communication systems or cause fault codes to be triggered. The system is also easy to install in the vehicle and configured to be compatible with most modern passenger vehicles. The system may also be configured to allow for customization and additional features such as power-off time delay or monitoring of other vehicle features that may draw on vehicle power.

In at least some embodiments, the system for detecting vehicle operational state includes an electrical parameter detector configured to be installed in a vehicle fuse box and a power controller in communication with the electrical parameter detector. The electrical parameter detector is configured to determine the state of vehicle operation by monitoring current draw and/or voltage differentials across points of a given fuse or relay in the fuse box of the vehicle. When the appropriate current draw and/or voltage differential is detected, a wireless signal may be sent to the power controller inside the cabin of the vehicle. The power controller may be configured to receive power from a vehicle source such as the OBD2 connector or a power socket inside the cabin. When the power controller receives the appropriate wireless signal from the electrical parameter detector, it is configured to activate power-consuming accessory devices as appropriate, such as dashcams or other cameras, logging devices, radar detectors, navigation systems, lighting systems, displays, and other accessories that should only be activated when the vehicle is operational. The power controller is also configured to turn off power-consuming accessory devices when the vehicle is not operational in order to eliminate parasitic power draws from such vehicle accessories.

The above described features and advantages, as well as others, will become more readily apparent to those of ordinary skill in the art by reference to the following detailed description and accompanying drawings. While it would be desirable to provide a method and system for power supply that provides one or more of the foregoing or other advantageous features as may be apparent to those reviewing this disclosure, the teachings disclosed herein extend to those embodiments which fall within the scope of any eventually appended claims, regardless of whether they include or accomplish one or more of the advantages or features mentioned herein.

### BRIEF DESCRIPTION OF THE DRAWINGS

FIG. 1 shows a block diagram of a detection device in association with a fuse box of a vehicle;

FIG. 2 shows a block diagram of the detection device of FIG. 1 installed in the fuse box, the detection device in communication with a power controller; and

FIG. 3 shows a side view of the detection device of FIG. 1 exposing the blades of the detection device.

### DESCRIPTION

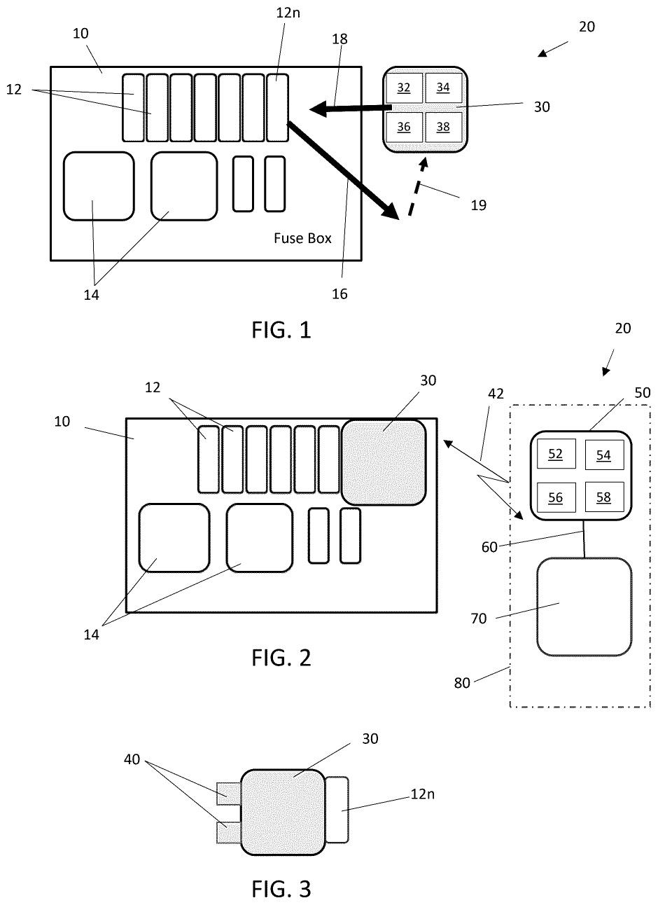

With general reference to FIGS. 1-3, a system 20 for determining vehicle operational state includes a detection device 30 configured to be installed in a vehicle fuse box 10 and a power controller 50 in communication with the detection device 30. The detection device 30 is configured to determine whether the vehicle is in operation with the powertrain on, or not in operation with the powertrain off. The power controller 50 is in communication with the detection device and is configured to receive a signal from the detection device 30 indicative of vehicle operational state. Depending on the vehicle operational state, the power controller 50 may be configured to turn a vehicle accessory on or off.

The fuse box 10 is an electrical safety device in the vehicle that operates to provide overcurrent protection in a vehicle electrical circuit. The fuse box 10 may include a plurality of fuses 12 and/or a plurality of relays 14, and/or other protection devices (e.g., circuit breakers). As shown in FIG. 1, one or more of the fuses is removed from an associated socket or other receptacle in the fuse box 10 (as noted by arrow 16), thus making room for the detection device 30 of the system 20. The detection device 30 is then inserted into the receptacle (or receptacles) from which the one or more fuses 12 were removed (as noted by arrow 18), thus replacing the one or more fuses 12 in the fuse box 10. Alternatively, if the detection device 30 is configured to replace one or more relays 14 (or other protection devices), the detection device 30 is inserted into the receptacle (or receptacles) from which the one or more relays were removed. In this manner the detection device 30 is installed in the fuse box 10 of a vehicle. Because the detection device 30 is configured for installation in a vehicle fuse box, the detection device 30 may also be referred to herein as a “fuse box unit.”

The detection device 30 includes a microprocessor 32 (or other logic/processing circuitry), a wireless signal transmitter 34 (which may also be provided by a transceiver), electronic detection circuitry 36, and a fuse/relay adapter 38, all included within or on a housing for the detection device 30. The electronic detection circuitry 36 is configured to monitor current draw and/or voltage differentials across two different points of a given fuse receptacle (or other receptacle) in the fuse box. For example, the electronic detection circuitry 36 may include a voltage divider that detects the existence of electrical power in a vehicle charging circuit (e.g., the existence of a current or voltage differential across a two points in the vehicle charging circuit). While the vehicle charging circuit is one example of a circuit that may include a fuse in the vehicle fuse box 10, it will be recognized that any number of different vehicle circuits with protection devices in the fuse box may be monitored by the detection device, such as the vehicle starting circuit, ignition system, or lighting circuit, to name a few.

The microprocessor 32 (or related processing circuitry) is configured to receive signals from the vehicle via the electronic detection circuitry 36 and determine an operational state of the vehicle. The detection device 30 is configured to determine the state of vehicle operation by monitoring an electrical parameter in the vehicle, wherein the “electrical parameter” in the vehicle is detected by any of various electrical signals such as current draw and/or voltage differentials and/or power and/or another electrical parameter across points of a given fuse or relay in the fuse box of the vehicle. Accordingly, the detection device 30 may also be referred to herein as a “electrical parameter detector.” The determination of vehicle power and associated operational states may be similar to that described in U.S. patent application Ser. No. 18/670,260, filed May 21, 2024, now U.S. Pat. No. 12,246,665, and/or U.S. patent application Ser. No. 19/075,758, filed Mar. 10, 2025, the contents of which are incorporated herein by reference in their entirety. For example, the determination of a vehicle operational state may involve detection of an increase in battery voltage in the vehicle charging circuit in excess of some threshold (e.g., 12.85V). Such an increase above a threshold voltage may be used to indicate that the engine has fired and the vehicle is in an operational state. As another example, the determination of an operational current flowing through a daytime running lamp circuit may also indicate that the vehicle is in an operational state. When the electrical parameter detector 30 detects the existence of operational power (e.g., an appropriate current draw and/or voltage differential within a circuit), a signal is sent to the power controller 50 inside the cabin of the vehicle indicating that the vehicle is in operation.

The transmitter 34 of the electrical parameter detector 30 is configured to communicate with the power controller 50. Specifically, the transmitter 34 of the electrical parameter detector is configured to send a wireless signal from the fuse box 10 where the electrical parameter detector 30 is located to the vehicle cabin 80 or other location outside the vehicle fuse box where the power controller 50 is mounted or otherwise located. The transmitter 34 may be a standalone transmitter or may also be included as part of a transceiver that is configured for two-way communications with the power controller 50. For convenience of installation of the system 20, the transmitter 34 may be a wireless transmitter configured to send wireless signals 42 to the power controller 50. The wireless signals 42 to the power controller 50 from the electrical parameter detector 30 may be provided by an appropriate continuous or periodic signal as allowed by the FCC for any frequency band being used. This signal may be packetized information through a protocol such as 802.11, Bluetooth, or Bluetooth Low Energy. While the transmitter 34 has been described herein as being “wireless”, in at least some embodiments, communications between the electrical parameter detector 30 and the power controller 50 may be a physical wired connection instead of a wireless connection.

Because the electrical parameter detector 30 is designed to replace a protective device (e.g., fuse or relay) in the fuse box, the electrical parameter detector 30 is also configured to perform the same functionality as the replaced protection device. Accordingly, in at least one embodiment, the electrical parameter detector includes a protective device adapter 38. The adapter 38 is configured to receive the fuse 12 or relay 14 (or other protective device) that was removed from the fuse box 10 in order to make room for the electrical parameter detector 30. The fuse/relay adapter 38 is provided on a housing of the electrical parameter detector 30 and includes a socket or other receptacle configured to receive a plug portion (or other connector) of the fuse 12 or relay 14 removed from the fuse box 10. Alternatively, instead of the fuse/relay adapter 38 that receives the original fuse/relay removed from the fuse box, the electrical parameter detector 30 may include a built-in protective device that completely replaces (i.e. provides a substitute component for) the original fuse or relay (or other adapter) that was removed from the fuse box 10 and provides the same functionality (e.g., overcurrent protection or relay). Accordingly, it will be recognized that the electrical parameter detector 30 is designed with connections such that it can fit into the receptacle of a fuse box 10 (e.g., as shown in the fuse box 10 in FIG. 2) and either (i) allow the original fuse or relay that was previously located in the receptacle to continue to be used in the vehicle by plugging such original fuse or relay into a receptacle in the electrical parameter detector 30 itself (e.g., as indicated by dotted line 19 in FIG. 1 wherein the electrical parameter detector 30 acts as a pass-through adapter) or (ii) replicate or emulate the original functionality of the original fuse or relay by similar functionality included the electrical parameter detector 30 itself. In the case where the electrical parameter detector 30 is equipped with similar functionality as that of the removed original fuse or relay, such functionality may be accomplished through the use of other electronic circuitry or controls or through the integration of a substantially similar component in the electrical parameter detector 30 as the component being replaced. In other words, the original fuse or relay would not be used in this situation, but the electrical parameter detector 30 would be designed to provide the same functionality of the original fuse or relay. The same functionality would be provided through alternate means if the original component is not used. For example, instead of a physical fuse, the electrical parameter detector could be electronics that monitor the current flow and would break the circuit if a certain current level was exceeded. Alternatively, instead of a physical relay, there could be electronics that alter the current path with electronic switches (e.g., MOSFETs) based on an input signal instead of using the means of a mechanical relay.

In various embodiments, the electrical parameter detector 30 may include a separate connection to a power or ground point in the fuse box. This connection may depend at least in part on the configuration of the electrical parameter detector 30 (which is likely the case for use as an adapter for a fuse, but may not be necessary for use as an adapter for a relay as both 12V power and ground connections would be provided in the existing socket).

As shown in FIG. 3, in order to facilitate insertion of the electrical parameter detector 30 into the desired receptacle of the vehicle fuse box 10, the electrical parameter detector 30 includes blades 40 or other plugs or coupling members that are configured for insertion into receptacles in the fuse box 10. Once the blades 40 are inserted into an appropriate receptacle in the fuse box 10, the electronic detection circuitry 36 and microprocessor 32 of the electrical parameter detector 30 are installed in the desired vehicle circuit configured to detect the presence of power in the circuit (thus indicating when the vehicle is in operation with the powertrain running). Thereafter, the electrical parameter detector 30 is also configured to send a wireless signal to the corresponding power controller 50 inside the passenger cabin.

With particular reference now to FIG. 2, the power controller 50 is configured for wireless communication with the electrical parameter detector 30 via a wireless signal 42 provided over a wireless communication channel. The power controller 50 includes a microprocessor 52, a wireless signal receiver 54, switching circuitry 56 configured to turn power on/off to any connected vehicle accessories, voltage converters 58 to alter voltage provided to accessories (if desired), and connections 60 for an accessory device 70. In at least some embodiments, the power controller 50 is arranged in the passenger cabin 80 and is connected to a vehicle power circuit (e.g., BATT+) through a vehicle interface, such as the OBD2 port inside the vehicle cabin or a power socket intended for passenger use. The power controller 50 is in communication with the electrical parameter detector 30 (and thus the power controller 50 may also be referred to herein as a “paired device”). When the power controller/paired device 50 receives a wireless signal from the electrical parameter detector 30 in the fuse box, it provides power to one or more accessory devices 70 plugged into the power controller 50. This provision of power generally results in the accessory devices 70 being turned on when the vehicle is in operation and turned off when the vehicle is not in operation. As discussed in further detail below, optional features such as time delays and manual overrides may also be included in the paired device 50.

The wireless signal receiver 54 (which may also be provided by a transceiver) is configured to receive a signal from the transmitter 34 of the electrical parameter detector 30 indicating that power to the vehicle is on. In at least some embodiments, the wireless signal 42 received at the paired device 50 from the electrical parameter detector 30 may be a continuous or periodic signal, as allowed by the FCC for any frequency band being used. This signal could be packetized information through a protocol such as 802.11, Bluetooth, or Bluetooth Low Energy. Accordingly, the wireless signal receiver 54 may be a Bluetooth receiver/transceiver.

The wireless signal 42 received at the receiver 54 of the power controller 50 is delivered to the microprocessor 52 of the power controller 50 for further processing. In at least some embodiments, the received signal 42 itself indicates an operational state of the vehicle. In other embodiments, the received signal 42 indicates an electrical parameter measured at the electrical parameter detector 30, and the microprocessor 52 determines an operational state of the vehicle based on the received electrical parameter. The microprocessor 52 is configured to control the switching circuitry 56 and the voltage converters 58 in order to control the power delivered to the vehicle accessories 70.

The switching circuitry 56 of the power controller 50 includes one or more electrical components configured to deliver electrical power to an accessory 70 (via an electrical connection 60 between the power controller 50 and the accessory 70) or deprive the accessory of power. For example, the switching circuitry 56 may be provided by one or more transistors provided by MOSFETs or other semiconductor devices. The switching circuitry 56 is connected to vehicle power (e.g., a connection to vehicle battery power, such as through an OBD2 port or vehicle power socket) and is controlled by the microprocessor 52. When the switching circuitry 56 is closed, power is delivered to one or more vehicle accessories 70. When the switching circuitry 56 is open, electrical power is not delivered to the vehicle accessories 70.

The voltage converters 58 of the power controller are configured to regulate power delivered to the vehicle accessories 70. The voltage converters 58 may include one or more transformers and associated semiconductor devices configured to alter the voltage provided to accessories. For example, the voltage converters 58 may be configured as step-down converters which transition the approximately +12V vehicle voltage to approximately +5V for use by one or more vehicle accessories 70.

The electrical connection 60 between the power controller 50 and the accessory 70 may be provided by any number of different means. For example, the electrical connection 60 may be provided by a power cable or connector that extends between the power controller 50 and the accessory. Alternatively, in at least some embodiments the power controller 50 may be incorporated into the accessory itself (e.g., arranged within a common housing).

As noted previously, the vehicle accessory 70 may be one or more of any of various accessories available for installation in a vehicle. These accessories 70 are typically aftermarket accessories, but in at least some embodiments, the system 20 may be used to deliver power to original equipment manufacturer (OEM) parts and accessories. Examples of aftermarket accessories that may be powered by the system include radar detectors, dashcams, heads-up displays, and interior lighting systems.

In view of the foregoing, it will be recognized that a system 20 is disclosed herein wherein the electrical parameter detector 30 is provided as a unit configured for placement within a vehicle fuse box 10 as a replacement for an existing fuse or relay inside the vehicle fuse box. The electrical parameter detector 30 communicates wirelessly with the paired device/power controller 50 that is provided as a passenger cabin unit. The electrical parameter detector 30 may allow the relay or fuse it replaces (or similar) to be plugged into it. Alternatively, the electrical parameter detector 30 may contain electronics to emulate/simulate the original current control. The power controller is configured to deliver power to a vehicle accessory based on the operational state of the vehicle.

In at least some embodiments, the delivery of power to the vehicle is dependent on a state of the vehicle and associated modes of the system 20. For example, similar to U.S. patent application Ser. No. 19/075,758, filed Mar. 10, 2025, the system 20 may be configured to deliver power different to the vehicle accessory 70 dependent on the system being in one of various modes/states such as SLEEP, WAKE, PARK MODE, etc.

### Method for Detection of an Operational State of a Vehicle

In view of the foregoing, it will be recognized that operation of the system 20 discloses a method for detecting an operational state of a vehicle. The method includes detecting an electrical parameter within a vehicle fuse box. The method further includes determining a vehicle operational state based on the detected electrical parameter. Either the vehicle operational state or the detected electrical parameter is then wirelessly transmitted to a power controller mounted in a remote location from the vehicle fuse box (e.g., a vehicle cabin). If the detected electrical parameter is the only signal transmitted to the power controller, the power controller is configured to determine the operational state of the vehicle based at least in part on the detected electrical parameter. Thereafter, with the operational state of the vehicle determined, the power controller controls power delivered to a vehicle accessory based at least in part on the determined vehicle operational state. The accessory is typically mounted in the cabin of the vehicle and may be a camera, radar detector, display, accessory lighting system, navigation system, or any other vehicle accessory.

### ALTERNATIVE EMBODIMENTS

While an exemplary embodiment of the system 20 for determining vehicle operational state has been described above, it will be recognized that alternative embodiments of the system are contemplated. In at least some embodiments, the system 20 for determining vehicle operational state forgoes the use of a wireless interface and instead uses a wire for communication between the electrical parameter detector 30 and the paired device 50. However, it will be recognized that this wired arrangement with one or more wires extending between the electrical parameter detector 30 in the fuse box and the paired device 50 in the passenger cabin would add a great deal of complexity to the installation as opposed to the above-disclosed wireless arrangement.

In another alternative embodiment, the electrical parameter detector 30 is configured for connection to the original unit in the fuse box and further configured to turn on power to certain ports inside the vehicle when desired, instead of having these ports always powered on even when the vehicle is not in operation. The installation using this method may be slightly more complicated than the original method as it would require the installation of two units in the fuse box and determining which, if any, fuses or relays could be emulated to control power at the appropriate points inside the passenger cabin. For example, consider and arrangement wherein in the original fuse box there is a fuse that controls power to a 12V power outlet inside the vehicle and this power is always on even if the vehicle is not in operation. The proposed alternative embodiment would involve an adapter or emulator that is installed in place of that original fuse to turn power on or off to the 12V power outlet, as desired. In this situation, it is assumed that the initially disclosed adapter is configured to determine that the vehicle is not in operation and would thus control a device that plugged into the fuse socket for the 12V power outlet to turn off power unless it detected the vehicle was in operation.

In another alternative embodiment, the electrical parameter detector 30 is positioned at a different vehicle location than the fuse box 10. In this embodiment, the electrical parameter detector 30 may be spliced into a wiring harness somewhere in the vehicle instead of in the fuse box 10. For example, the electrical parameter detector 30 may be spliced in as a short extension cable to a harness running to the headlights (e.g., daytime running lights that would be on when vehicle is operational). As another example, the electrical parameter detector could be spliced into a mass airflow sensor that would always have 5V running to it when the engine is active.

In yet another alternative embodiment, instead of one unit inside the passenger cabin to distribute power to multiple devices, each individual vehicle accessory 70 (e.g., radar detector, dashcam, heads-up display, interior lighting system, etc.) includes its own wireless receiver/power controller 50 (i.e., to control its own power state as necessary) which is configured to receive wireless signals 42 from the electrical parameter detector 30.

The word “vehicle” as used herein is intended to refer to any device used for transporting people or goods, such as cars, trucks, carts, cycles, boats, etc. The word “receptacle” as used herein refers to one coupling structure that is configured to receive another coupling structure. While a “receptacle” is typically a female structure configured to receive a male structure (e.g., a socket configured to receive a plug of the electrical parameter detector) in most embodiments, in other embodiments a “receptacle” may refer to a male structure that receives a female structure (e.g., a plug configured to fit into a socket of the electrical parameter detector).

Although the various embodiments and applications for the power supply have been provided herein, it will be appreciated by those of skill in the art that other implementations and adaptations are possible. Furthermore, aspects of the various embodiments described herein may be combined or substituted with aspects from other features to arrive at different embodiments from those described herein. Thus, it will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by any eventually appended claims.

What is claimed is:

1. A system for determining vehicle operational state comprising:
a vehicle including a vehicle fuse box comprising a plurality of receptacles;
an electrical parameter detector inserted into one of the plurality of receptacles in the vehicle fuse box, the electrical parameter detector configured to detect an electrical parameter indicative of a vehicle operational state;
a power controller mounted outside of the vehicle fuse box, the power controller in communication with the electrical parameter detector, the power controller configured to receive a signal from the electrical parameter detector indicative of an operational state of the vehicle; and
a vehicle accessory connected to the power controller, wherein the power controller is configured to deliver power to the vehicle accessory based on the operational state of the vehicle.

2. The system of claim 1 wherein the power controller and the vehicle accessory are located in a vehicle cabin.

3. The system of claim 1 wherein the communication between the electrical parameter detector and the power controller is wireless communication.

4. The system of claim 1 wherein the power controller is connected to a vehicle power circuit and includes at least one voltage converter configured to alter a voltage provided by the vehicle power circuit for delivery to the vehicle accessory.

5. The system of claim 1 wherein the electrical parameter detector includes electronic detection circuitry configured to detect an electrical parameter in a vehicle circuit, logic circuitry configured to determine an operational state of the vehicle based at least in part on the detected electrical parameter, and a transmitter configured to transmit the operational state of the vehicle to the power controller.

6. The system of claim 1 wherein the electrical parameter detector includes a protective device adapter including a receptacle configured to receive a plug of a protective device from the vehicle fuse box.

7. The system of claim 1 wherein vehicle accessory is one of a camera, radar detector, display, accessory lighting system, or navigation system.

8. A method for determining an operational state of a vehicle comprising:
detecting an electrical parameter within a vehicle fuse box;
determining a vehicle operational state based on the detected electrical parameter; and
controlling power delivered to a vehicle accessory based at least in part on the determined vehicle operational state.

9. The method of claim 8 further comprising transmitting the detected electrical parameter or the determined vehicle operational state from the vehicle fuse box to a power controller.

10. The method of claim 9 wherein transmission of the detected electrical parameter or the determined vehicle operational state is a wireless transmission.

11. The method of claim 9 wherein the power controller and the vehicle accessory are positioned in a cabin of the vehicle.

12. The method of claim 11 wherein the vehicle accessory is one of a camera, radar detector, display, accessory lighting system, or navigation system.

13. The method of claim 9 wherein a power controller is configured to control the power delivered to the vehicle accessory, and the power controller is connected to a vehicle power circuit.

14. The method of claim 9 wherein an electrical parameter detector is configured to detect the electrical parameter within the vehicle fuse box, the electrical parameter detector including logic circuitry configured to determine an operational state of the vehicle based at least in part on the detected electrical parameter, and a transmitter configured to transmit the operational state of the vehicle to the power controller.

15. The method of claim 14 wherein the electrical parameter detector includes a protective device adapter with a receptacle configured to receive a plug of a protective device from the vehicle fuse box.

16. A system for determining an operational state of a vehicle, the system comprising:
an electrical parameter detector connected to a vehicle electrical circuit, the electrical parameter detector configured to detect electrical parameter indicative of a vehicle operational state; and
a power controller in wireless communication with the electrical parameter detector and connected to a vehicle power circuit within a cabin of the vehicle, the power controller including switching circuitry configured to deliver power to a vehicle accessory depending on the vehicle operational state.

17. The system of claim 16 wherein the electrical parameter detector is connected to a receptacle in a vehicle fuse box.

18. The system of claim 17 wherein the power controller further includes at least one voltage converter configured to alter a voltage provided by the vehicle power circuit for delivery to the vehicle accessory.

19. The system of claim 17 wherein the electrical parameter detector includes a protective device adapter with a receptacle configured to receive a plug of a protective device from the vehicle fuse box.

20. The system of claim 17 wherein the electrical parameter detector includes electronic components configured to provide overcurrent protection or a relay within the vehicle fuse box.
